(19) United States
(12) Patent Application Publication
(10) Pub. No.: US 2018/0026326 A1
(43) Pub. Date: Jan. 25, 2018

(54) HEAT DISSIPATION SHEET-INTEGRATED ANTENNA MODULE

(71) Applicant: AMOGREENTECH CO., LTD., Gyeonggi-do (KR)

(72) Inventors: Jin-Won NOH, Gwangju (KR); Hyung-Il BAEK, Gyeonggi-do (KR); Beom-Jin KIM, Gyeonggi-do (KR); Chung-Ha BACK, Gyeongsangbuk-do (KR); Min-Ho WON, Incheon (KR)

(21) Appl. No.: 15/543,040

(22) PCT Filed: Jan. 14, 2016
(86) PCT No.: PCT/KR2016/000414

§ 371 Date: Jul. 12, 2017

(30) Foreign Application Priority Data
Jan. 21, 2015 (KR) 10-2015-0010067

(51) Int. Cl. H01Q 1/02; H01Q 1/52; H05K 7/20; H01Q 1/50

(52) U.S. Cl. CPC H01Q 1/02; H01Q 1/50; H01Q 1/52; H05K 7/2039; H01Q 1/243

(57) ABSTRACT

Provided is a heat dissipation sheet-integrated antenna module which maintains a heat dissipation performance and an antenna performance to be equal to or better than those of a structure where a heat dissipation sheet and an antenna module are separated. The presented heat dissipation sheet-integrated antenna module is configured by coupling a heat dissipation sheet having a slit formed therein to an upper or lower part of an antenna pattern. Therefore, the antenna pattern of the antenna module is operated as an auxiliary heat dissipation member or the heat dissipation sheet is operated as an auxiliary radiator of the antenna module.

### TECHNICAL FIELD

The present invention relates generally to an antenna module and, more particularly, the present invention relates to a heat dissipation sheet-integrated antenna module that is provided integrally with a heat dissipation sheet for dissipating heat generated in a portable device.

The present application claims priority to Korean Patent Application No. 10-2015-0010067, filed Jan. 21, 2015, the entire contents of which is incorporated herein for all purposes by this reference.

### BACKGROUND ART

Due to advances in technology, high performance, size reduction, and weight reduction of electronic devices are emerging as an important issue.

As electronic devices have become more sophisticated, compact, and lightweight, internal spaces of the devices have been reduced, and thus heat generated in the devices is not efficiently dissipated. If electronic devices cannot efficiently dissipate heat generated therein, problems such as after-image on the screen, system failure, shortening of product life cycle, etc. may be caused, and in severe cases, explosion or fire may be caused.

In particular, a portable terminal such as a smart phone, a tablet, etc, is required to be reduced in size and weight to maximize the portability and convenience to a user. In addition, as the performance of the portable terminal progresses, integrated components are mounted in a small space, and heat generated in the portable terminal increases, and thus the performance of the portable terminal deteriorates due to influence of heat on the components.

Further, since the portable terminal is used in a state in which the portable terminal is in contact with the user's hand or face, the user's skin is damaged due to heat generated in the portable terminal.

Accordingly, various heat dissipation materials are used in the portable terminal to solve problems caused by internal heat generation of the portable terminal.

For example, a heat dissipation sheet is made of a metal material and is attached to components (e.g. a display) installed in a portable terminal. The heat dissipation sheet dissipates heat generated from the components in both the vertical and horizontal directions.

However, since the heat dissipation sheet is made of a metal material for efficient heat dissipation, there is a problem in that when the heat dissipation sheet is attached to an antenna module installed in the portable terminal, radiation performance of the antenna module is deteriorated.

In particular, in the case of a portable terminal capable of attaching and detaching a battery, an antenna module is mounted inside or on a side surface of the battery. In this case, when a heat dissipation sheet is applied to a back cover (rear (battery) case) for heat dissipation of the portable terminal, the heat dissipation sheet lowers communication performance of the antenna module, and thus the heat dissipation sheet is applied to a region except a region where the antenna module is mounted. As a result, an area of the heat dissipation sheet is reduced, thereby deteriorating the heat radiation effect.

In addition, when the heat dissipation sheet is mounted in the portable terminal while being separated from the antenna module, space utilization is lowered and thus it is difficult to reduce the size of the portable terminal.

### DISCLOSURE

### Technical Problem

Accordingly, the present invention has been made keeping in mind the above problems occurring in the prior art, and an object of the present invention is to provide a heat dissipation sheet-integrated antenna module, in which a slit is formed at a heat dissipation sheet attached to an antenna module, whereby an antenna pattern of the antenna module serves as the heat dissipation sheet, or the heat dissipation sheet serves as an auxiliary radiator of the antenna module.

### Technical Solution

In order to accomplish the above object, the present invention provides a heat dissipation sheet-integrated antenna module, the antenna module including: an antenna pattern; and a heat dissipation sheet having one or more slits and being coupled to the antenna pattern.

The heat dissipation sheet may be coupled to an upper surface of the antenna pattern, such that the antenna pattern may be partially exposed through the one or more slits.

The antenna module may further include a base sheet attached to the antenna pattern, wherein the heat dissipation sheet may be attached to the base sheet and coupled to the antenna pattern.

The heat dissipation sheet may include: a first heat dissipation member having a slit and being coupled to the antenna pattern; and a second heat dissipation member having a slit and coupled to the antenna pattern at a location spaced apart from the first heat dissipation member, wherein the antenna pattern may be partially exposed through a slit formed at a region where the first and second heat dissipation members are spaced apart from each other, and through the slits formed at the first and second heat dissipation members.

The heat dissipation sheet may further include a third heat dissipation member spaced apart from the first and second heat dissipation members at the region where the first and second heat dissipation members are spaced apart from each other, the third heat dissipation member being coupled to the antenna pattern, wherein the antenna pattern may be partially exposed through slits formed at regions where the first and second heat dissipation members are spaced apart from the third heat dissipation member.

The heat dissipation sheet may include: a first heat dissipation member provided at a side thereof with a slit and coupled to the antenna pattern; and a second heat dissipation member provided at a side thereof with a slit and coupled to the antenna pattern at a location spaced apart from the first heat dissipation member, wherein the antenna pattern may be partially exposed through a slit formed at a region where the first and second heat dissipation members are spaced apart from each other, and through the slits provided at the first and second heat dissipation members. Here, the first and second heat dissipation members may be placed such that the sides thereof at which the slits are provided face each other.

The heat dissipation sheet may include an insulation layer composed of a porous substrate having a plurality of fine pores that form air pockets capable of trapping air, or of a graphite layer. Here, the porous substrate may include one of a nano-fiber web, a non-woven fabric, and a laminated structure of the nano-fiber web and the non-woven fabric, each of the nano-fiber web, the non-woven fabric, and the laminated structure having a plurality of pores formed by accumulating nano-fibers.

### Advantageous Effects

According to the present invention, a heat dissipation sheet-integrated antenna module is provided such that a heat dissipation sheet is provided with a slit and is provided integrally with an antenna module, and thus compared with the prior art in which the antenna module and the heat dissipation sheet are provided separately, an area of the heat dissipation sheet is increased, thereby maximizing heat dissipation effect, and maintaining antenna performance to be equal to or better than that of the prior art. In particular, even in the case that the heat dissipation sheet is applied to a back cover, the heat dissipation sheet-integrated antenna module can ensure antenna performance equal to that of the case where the heat dissipation sheet is absent, while maintaining heat dissipation performance.

Further, the heat dissipation sheet-integrated antenna module is provided such that the heat dissipation sheet is provided with the slit and is provided integrally with the antenna module, and thus an antenna pattern and a base sheet that are made of metal serve as an auxiliary heat dissipation member, thereby maximizing heat dissipation effect.

Further, the heat dissipation sheet-integrated antenna module is provided such that the heat dissipation sheet is provided with the slit and is provided integrally with the antenna module, and thus the heat dissipation sheet serves as an auxiliary radiator of the antenna module by coupling between the antenna pattern and the heat dissipation sheet in a region where the slit is formed, thereby maximizing antenna performance.

### DESCRIPTION OF DRAWINGS

FIGS. 1 and 2 are views showing a heat dissipation sheet-integrated antenna module according to an embodiment of the present invention.

FIGS. 3 to 16 are views showing a heat dissipation sheet shown in FIGS. 1 and 2.

FIGS. 17 to 27 are views showing a comparison of antenna properties between a heat dissipation sheet separated-antenna pattern in the prior art and the heat dissipation sheet-integrated antenna module according the embodiment of the present invention.

### MODE FOR INVENTION

Hereinbelow, a preferred embodiment of the present invention will be described in detail with reference to the accompanying drawings such that the invention can be easily embodied by one of ordinary skill in the art to which this invention belongs. Reference now should be made to the drawings, in which the same reference numerals are used throughout the different drawings to designate the same or similar components. Further, when it is determined that the detailed description of the known art related to the present invention might obscure the gist of the present invention, the detailed description thereof will be omitted.

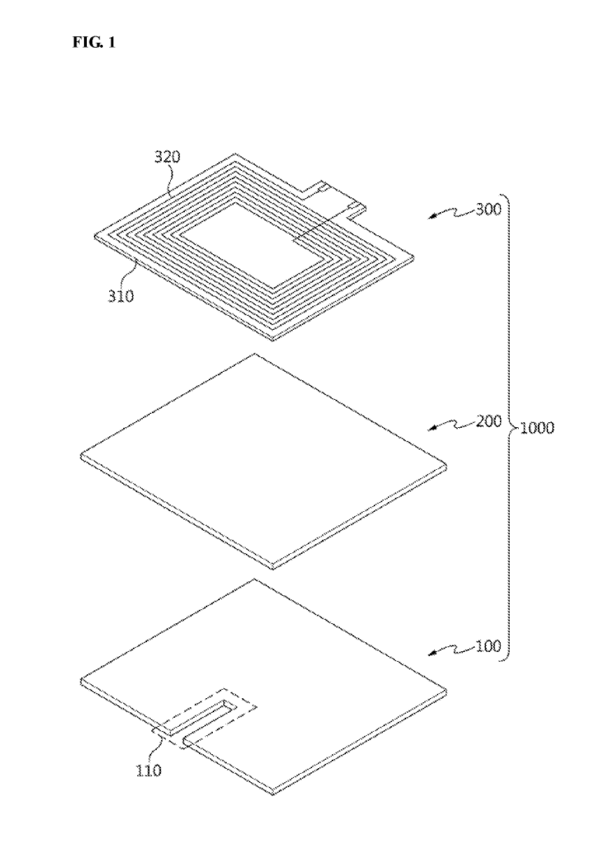

As shown in FIG. 1, a heat dissipation sheet-integrated antenna module 1000 includes a heat dissipation sheet 100, a base sheet 200 coupled to an upper surface of the heat dissipation sheet 100, and an antenna pattern 300 coupled to an upper surface of the base sheet 200.

The heat dissipation sheet 100 is provided such that a lower surface thereof is placed on a portable terminal. In other words, the heat dissipation sheet 100 is placed on an upper surface of a component installed in the personal terminal to dissipate heat generated from a corresponding component.

The heat dissipation sheet 100 may be provided with at least one slit. That is, the heat dissipation sheet 100 has a slit formed at a part of a region overlapping the antenna pattern 300. Accordingly, the heat dissipation sheet 100 serves as an auxiliary radiator of the antenna pattern 300 through coupling with the antenna pattern 300 through the slit.

The base sheet 200 is coupled at an upper surface thereof to the antenna pattern 300, and at the lower surface thereof to the heat dissipation sheet 100. Here, the base sheet 200 serves as a shielding sheet performing shielding between the antenna pattern 300 and components of the portable terminal. The base sheet 200 is made of a material such as a ferrite sheet, a polymer sheet, a nanoribbon sheet, an iron-based sheet, etc.

The antenna pattern 300 is formed by printing a micro-line in a loop shape on an upper surface of a flexible printed circuit board 310. Of course, the antenna pattern 300 may be formed in a loop shape in which a wire 320 is wound a plurality of times in a central direction of the upper surface of the base sheet 200 along a circumference of the base sheet 200. Here, the antenna pattern 300 is made of metal such as copper (Cu), aluminum (Al), silver (Ag), etc.

Herein, the base sheet 200 and the antenna pattern 300 may be coupled to the heat dissipation sheet 100 such that the base sheet and the antenna pattern serve as an auxiliary radiator. In other words, the base sheet 200 and the antenna pattern 300 that are made of metal dissipate heat generated from the components, thereby achieving improved heat dissipation performance.

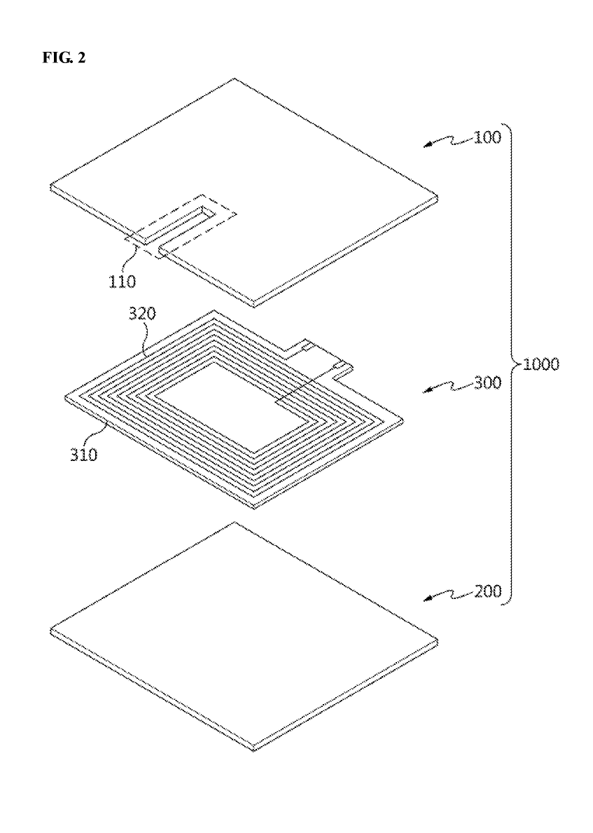

Meanwhile, as shown in FIG. 2, the heat dissipation sheet-integrated antenna module 1000 may include a base sheet 200, an antenna pattern 300 coupled to an upper surface of the base sheet 200, and a heat dissipation sheet 100 coupled to an upper surface of the antenna pattern 300.

The base sheet 200 is coupled at an upper surface thereof to the antenna pattern 300, and a lower surface thereof to a component of the portable terminal. Here, the base sheet 200 serves as a shielding sheet performing shielding between the antenna pattern 300 and components of the portable terminal. The base sheet 200 is made of a material such as a ferrite sheet, a polymer sheet, a nanoribbon sheet, an iron-based sheet, etc.

The antenna pattern 300 is formed by printing a micro-line in a loop shape on an upper surface of a flexible printed circuit board 310. Of course, the antenna pattern 300 may be formed in a loop shape in which a wire 320 is wound a plurality of times in a central direction of the upper surface of the base sheet 200 along a circumference of the base sheet 200. Here, the antenna pattern 300 is made of metal such as copper (Cu), aluminum (Al), silver (Ag), etc.

Herein, the base sheet 200 and the antenna pattern 300 may be coupled to the heat dissipation sheet 100 such that the base sheet and the antenna pattern serve as an auxiliary radiator. In other words, the base sheet 200 and the antenna pattern 300 that are made of metal dissipate heat generated from the components, thereby achieving improved heat dissipation performance.

The heat dissipation sheet 100 is coupled to the upper surface of the antenna pattern 300. In other words, the heat dissipation sheet 100 is coupled to the upper surface of the antenna pattern 300 to dissipate heat generated from the component of the portable terminal to which the base sheet 200 is coupled. Here, the heat dissipation sheet 100 may be provided with at least one slit. Here, the heat dissipation sheet 100 is provided with a slit formed at a part of a region overlapping the antenna pattern 300. Accordingly, the heat dissipation sheet 100 serves as the auxiliary radiator of the antenna pattern 300 through coupling with the antenna pattern 300 through the slit.

Herein, the heat dissipation sheet 100 is formed in various shapes and sizes depending on the size, position, etc. of the portable terminal to which the heat dissipation sheet is mounted, and is provided with one or more slits. An example of a structure of the heat dissipation sheet 100 will now be described with reference to the accompanying drawings.

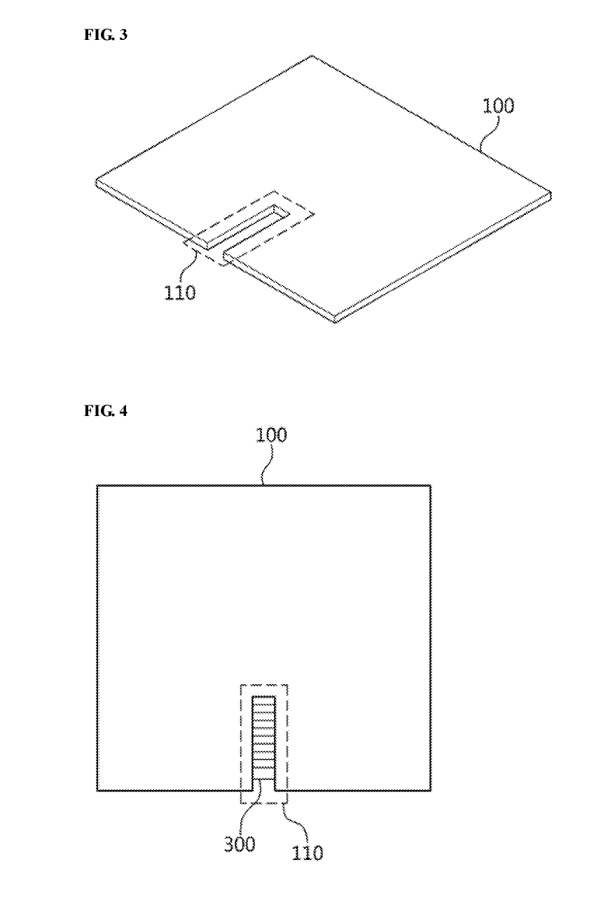

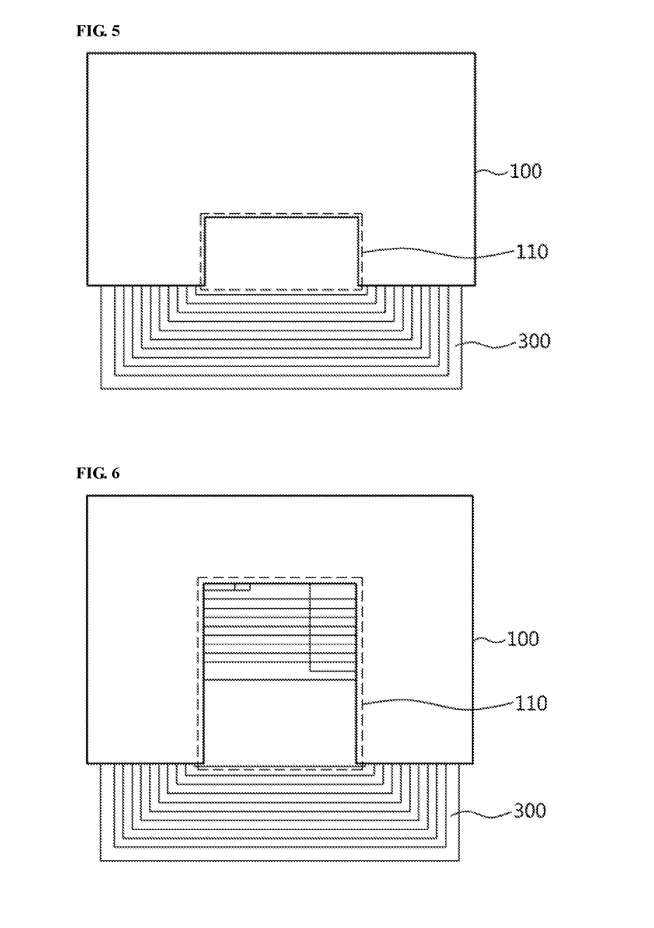

Referring to FIG. 3, the heat dissipation sheet 100 is formed in a rectangular shape, and is provided with one slit such that the heat dissipation sheet is coupled to an upper part of the antenna pattern 300. Accordingly, as shown in FIG. 4, the antenna pattern 300 is partially exposed through a first slit 110 formed at the heat dissipation sheet 100. Here, the first slit 110 is formed in a direction from an end to a center point of the heat dissipation sheet 100, and the size and shape of the first slit 110 may be varied and thus the exposed area and shape of the antenna pattern 300 may change (see FIGS. 5 and 6).

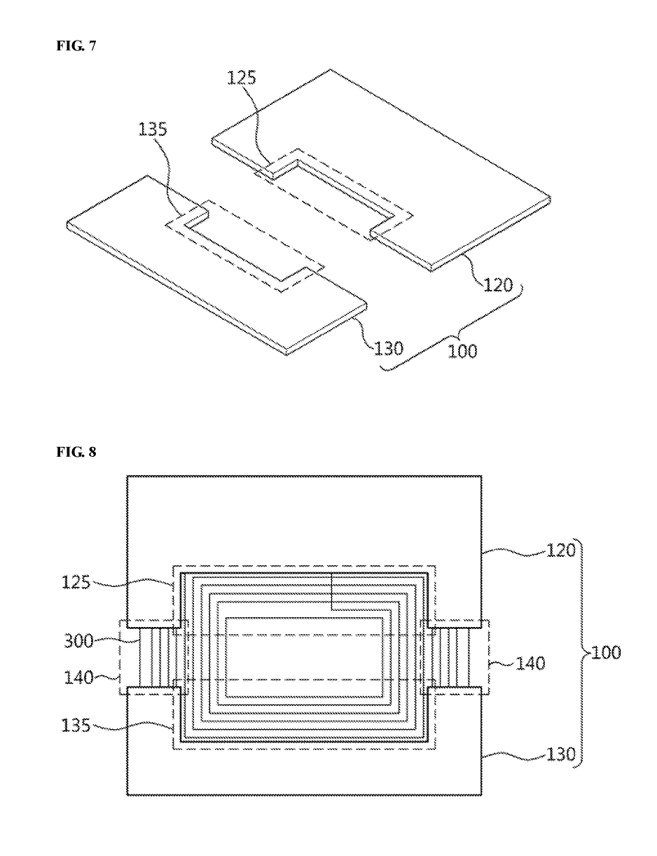

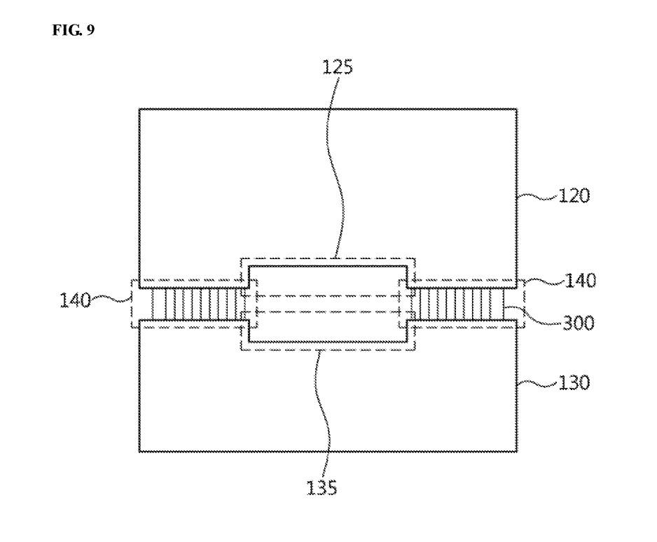

Referring to FIG. 7, the heat dissipation sheet 100 may include a first heat dissipation member 120 and a second heat dissipation member 130. The first heat dissipation member 120 is formed in a rectangular shape, and is provided with a second slit 125 formed in a direction from an end to a center point of the first heat dissipation member. The second heat dissipation member 130 is formed in a rectangular shape, and is provided with a third slit 135 formed in a direction from an end to a center point of the second heat dissipation member. The first and second heat dissipation members 120 and 130 are spaced apart from each other by a predetermined distance such that a fourth slit 140 is formed, and are coupled to the upper part of the antenna pattern 300. The first and second heat dissipation members are placed such that the sides thereof where the second and third slits 125 and 135 are formed face each other. Accordingly, as shown in FIGS. 8 and 9, the antenna pattern 300 is partially exposed through the second slit 125 to the fourth slit 140.

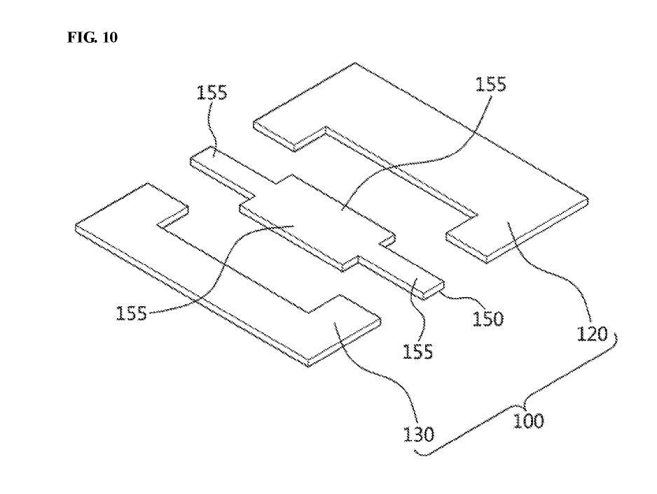

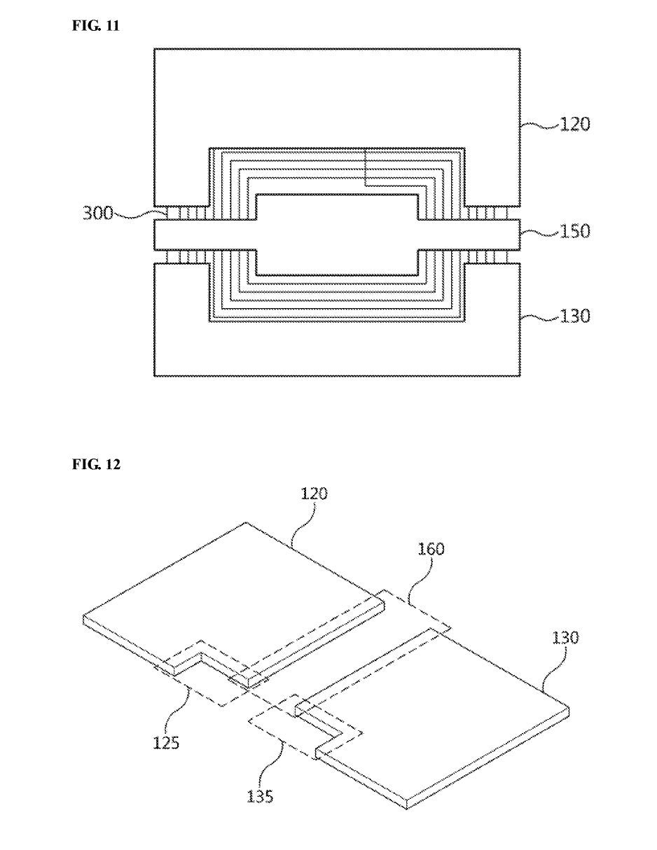

Herein, as shown in FIG. 10, the heat dissipation sheet 100 may further include a third heat dissipation member 150. The third heat dissipation member 150 is formed in a cross shape and is provided with four protrusions 155. The third heat dissipation member 150 is spaced apart from the first and second heat dissipation members 120 and 130 by a predetermined distance at a region where the first and second heat dissipation members 120 and 130 are spaced apart from each other. Accordingly, as shown in FIG. 11, the antenna pattern 300 is partially exposed through the region where the first and second heat dissipation members 120 and 130 are spaced apart from each other.

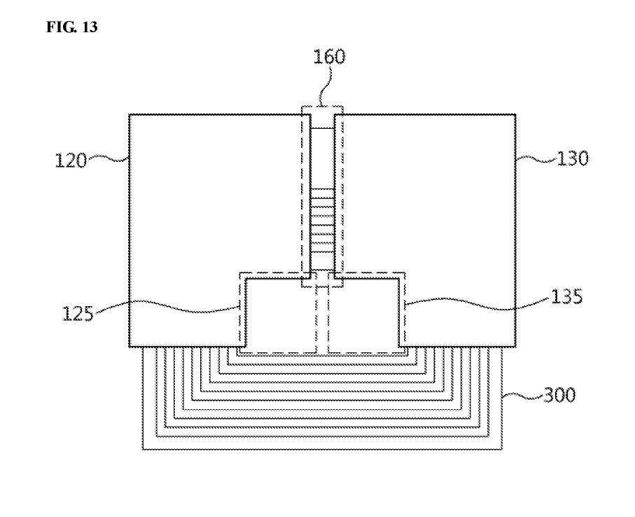

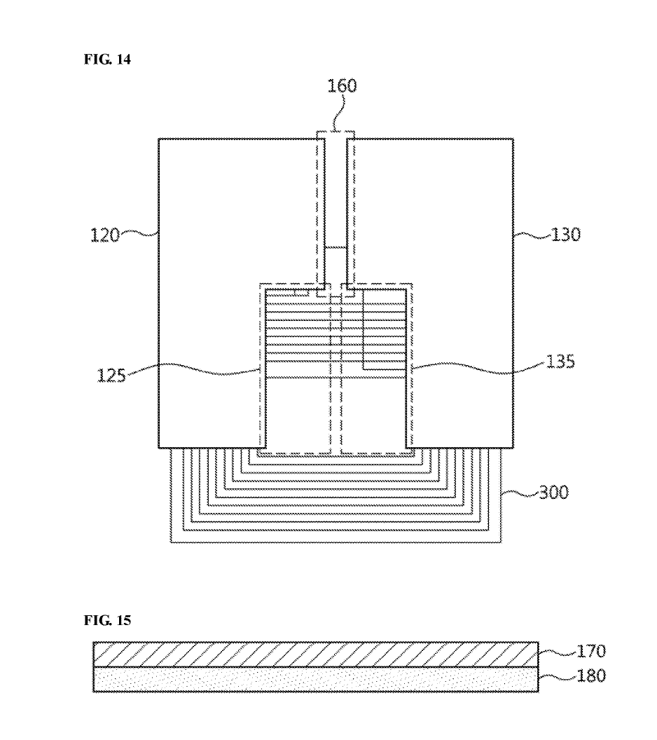

As shown in FIG. 12, the heat dissipation sheet 100 may include a first heat dissipation member 120 formed in a rectangular shape and provided at a corner thereof with a rectangular second slit 125, and a second heat dissipation member 130 formed in a rectangular shape and provided at a corner thereof with a rectangular third slit 135. The first and second heat dissipation members 120 and 130 are placed such that the corners thereof where the second and third slits are provided face each other, the first and second heat dissipation members being coupled to the upper part of the antenna pattern 300. Here, the first and second heat dissipation members 120 and 130 are spaced apart from each other by a predetermined distance such that a fifth slit 160 is formed. Accordingly, as shown in FIGS. 13 and 14, the antenna pattern 300 is partially exposed through the second slit 125 to the fifth slit 160.

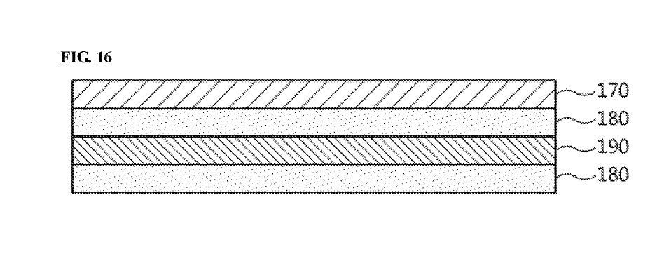

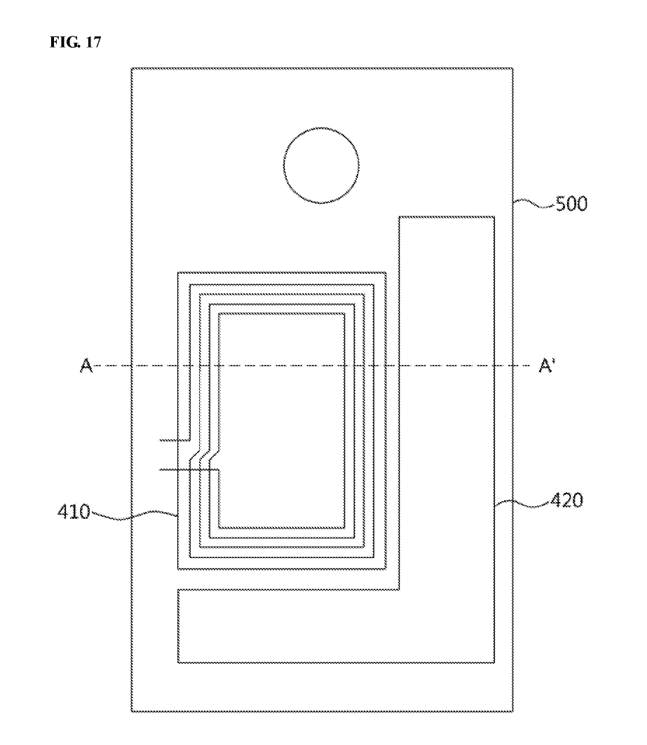

The structure of the heat dissipation sheet 100 of the heat dissipation sheet-integrated antenna module 1000 according to the embodiment of the present invention will be described with reference to FIGS. 15 and 16 as follows.

As shown in FIG. 15, the heat dissipation sheet 100 may include a heat dissipation layer 170 spreading and dissipating heat, and an adhesive layer 180 provided on the heat dissipation layer 170.

The heat dissipation layer 170 may include a plate-like member having a thermal conductivity of approximately equal to or greater than 200 W/mk. Here, the heat dissipation layer 170 may include one of copper (Cu), aluminum (Ag), silver (Ag), nickel (Ni), and graphite, or a laminate structure of two or more thereof, each of the copper, the aluminum, the silver, the nickel, the graphite, and the laminated structure having a thermal conductivity of approximately 200 to 3000 W/mk.

The heat dissipation layer 170 may have a double structure including a first heat dissipation layer 170 having a first thermal conductivity and spreading transferred heat and a second heat dissipation layer 170 having a second thermal conductivity different from the first thermal conductivity and spreading heat transferred in the first heat dissipation layer 170.

Here, the first thermal conductivity of the first heat dissipation layer 170 and the second thermal conductivity of the second heat dissipation layer 170 may be the same or different from each other. When the first and second thermal conductivity are different from each other, the first thermal conductivity of the first heat dissipation layer 170 is lower than the second thermal conductivity of the second heat dissipation layer 170, and the first heat dissipation layer 170 having a relatively low thermal conductivity is coupled to a heat-generating component by one of attachment, contact, and proximity.

Further, the first heat dissipation layer 170 and the second heat dissipation layer 170 may be diffusion bonded to each other. In this case, a junction layer formed by diffusion bonding may be provided between the first heat dissipation layer 170 and the second heat dissipation layer 170.

Herein, the heat dissipation layer may include one of a first structure in which the first heat dissipation layer 170 is made of one of Al, Mg, and Au and the second heat dissipation layer 170 is made of Cu; a second structure in which the first heat dissipation layer 170 is made of Cu and the second heat dissipation layer 170 is made of Ag; and a third structure in which the first heat dissipation layer 170 is made of one of Al, Mg, Au, Ag, and Cu and the second heat dissipation layer 170 is made of graphite.

The adhesive layer 180 may include one of acrylic, epoxy, aramid-based, urethane-based, polyamide-based, polyethylen-based, EVA-based, polyester-based, and PVC-based adhesives. Of course, the adhesive layer 180 may be a web-shaped hot melt adhesive sheet having a plurality of pores formed by accumulating fibers capable of being thermally bonded, or may be a non-pore hot melt adhesive sheet.

Meanwhile, as shown in FIG. 16, the heat dissipation sheet 100 may include a heat dissipation layer 170 spreading and dissipating heat, an adhesive layer 180 provided on the heat dissipation layer 170, an insulation layer 190 adhering at a first surface thereof to the adhesive layer 180 and suppressing heat transfer, and an adhesive layer 180 provided on a second surface of the insulation layer 190. Here, the adhesive layer 180 provided on the second surface of the insulation layer 190 is for adhering to a component of an electronic device.

The insulation layer 190 may include a plate-like member having a thermal conductivity equal to or less than 20 W/mk. In addition, the insulation layer 190 may include a porous substrate having a plurality of fine pores that form air pockets capable of trapping air, or a graphite layer. Here, the porous substrate enables air to be used as an insulation material by trapping air in the fine pores and suppressing convection of air.

For example, the porous substrate may include a nano-web having a plurality of pores formed by an electrospinning method, a non-woven fabric having a plurality of pores, polyether sulfone (PES), etc., and a laminated structure thereof. Further, any material can be used as long as it has a plurality of pores and performs an insulating function in the vertical direction. Here, the pore size of the porous substrate may be several tens of nm up to less than 5 μm.

Herein, the porous substrate may include one of a nano-fiber web, a non-woven fabric, and a laminated structure thereof, each of the nano-fiber web, the non-woven fabric, and the laminated structure having a plurality of pores formed by accumulating nano-fibers. Here, the nano-fiber web is formed as a nano-fiber web having a plurality of fine pores by preparing a spinning solution by mixing a high-polymer material suitable for electrospinning and having excellent heat resistance and a solvent at a predetermined ratio, forming nano-fibers by electrospinning the spinning solution, and accumulating the nano-fibers.

As the diameters of the nano-fibers decrease, the specific surface areas of the nano-fibers increase and the air trap capacity of the nano-fiber web having the plurality of fine pores increases, thereby improving heat insulation performance. Thus, a diameter of the nano-fibers may be in the range of 0.3 to 5 μm, and the porosity of the fine pores may be in the range of 50 to 80%.

In general, it is known that air is an excellent insulation material having low thermal conductivity, but is not used as the insulation material due to convection. However, since the insulation layer is configured in a nano-web form having a plurality of fine pores, air is prevented from convection and is trapped in the respective fine pores, thereby exhibiting excellent heat insulating properties that air itself possesses.

The spinning method for preparing the nano-fiber web may include any one selected from electrospinning, air-electrospinning (AES), electrospray, electrobrown spinning, centrifugal electrospinning, flash-electrospinning. The spinning method for producing the nano-fiber web may include any one selected from electrospinning, air-electrospinning (AES), electrospraying, electrobrown spinning, centrifugal electrospinning, and flash-electrospinning.

The polymer material used to produce the nano-fiber web may include one of, for example, oligomer polyurethane, polymer polyurethane, PS (polystylene), PVA (polyvinylalchol), PMMA (polymethyl methacrylate), PLA (polylactic acid), PEO (polyethyleneoxide), PVAc (polyvinylacetate), PAA (polyacrylic acid), PCL (polycaprolactone), PAN (polyacrylonitrile), PVP (polyvinylpyrrolidone), PVC (polyvinylchloride), nylon, PC (polycarbonate), PEI (polyetherimide), PVdF (polyvinylidene fluoride), PEI (polyetherimide), PES (polyesthersulphone) or a mixture thereof.

The solvent may include at least one selected from the group consisting of DMA (dimethyl acetamide), DMF (N,N-dimethylformamide), NMP (N-methyl-2-pyrrolidinone), DMSO (dimethyl sulfoxide), THF (tetra-hydrofuran), DMAc (di-methylacetamide), EC (ethylene carbonate), DEC (diethyl carbonate), DMC (dimethyl carbonate), EMC (ethyl methyl carbonate), PC (propylene carbonate), water, acetic acid, and acetone.

The nano-fiber web is prepared by the electrospinning method, and thus thickness of the nano-fiber web is determined according to a spinning dose of a spinning solution. Accordingly, it is easy to adjust the thickness of the nano-fiber web to a desired level.

As described above, since the nano-fiber web is formed as a nano-fiber web in which nano-fibers are accumulated by a spinning method, the nano-fiber web can be formed to have a plurality of fine pores without an additional process, and the size of the fine pores can be adjusted according to a spinning dose of a spinning solution. Thus, it is possible to finely form a plurality of pores, and thus heat transfer inhibition performance is excellent, thereby achieving improved heat insulation performance.

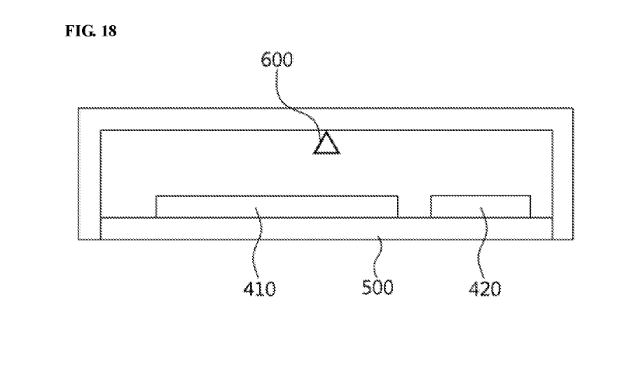

As shown in FIG. 17, when an antenna pattern 410 and a heat dissipation sheet 420 are provided separately and mounted on a back cover 500, the heat dissipation sheet 420 is applied to a region other than a region where the antenna pattern 410 is mounted in order to prevent degradation of communication performance of the antenna pattern 410. Here, referring to FIG. 18 showing a cross-section taken along line A-A′ of FIG. 17, since an area of the heat dissipation sheet 420 is reduced, and a hot spot 600 (i.e., a main heat generating region) is placed in the region where the antenna pattern 410 is mounted, heat dissipation performance is degraded.

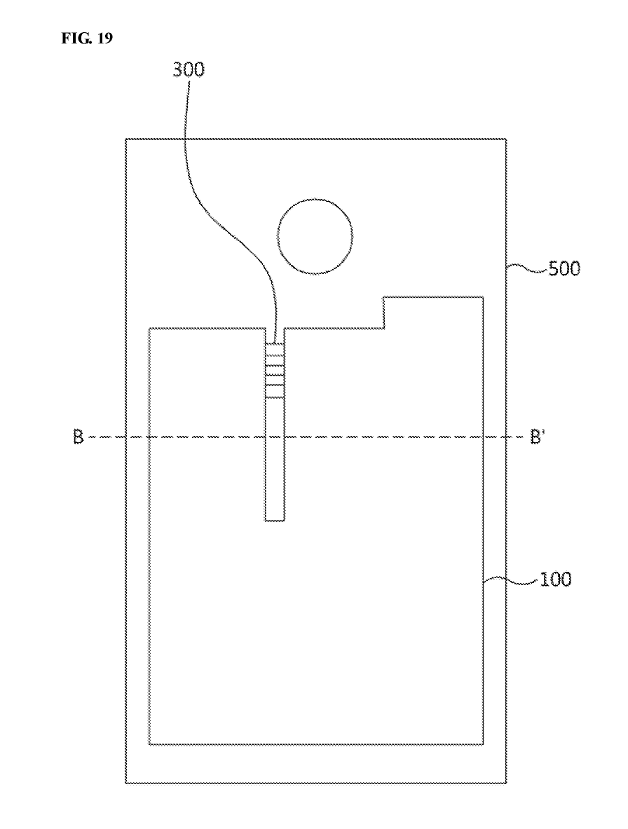

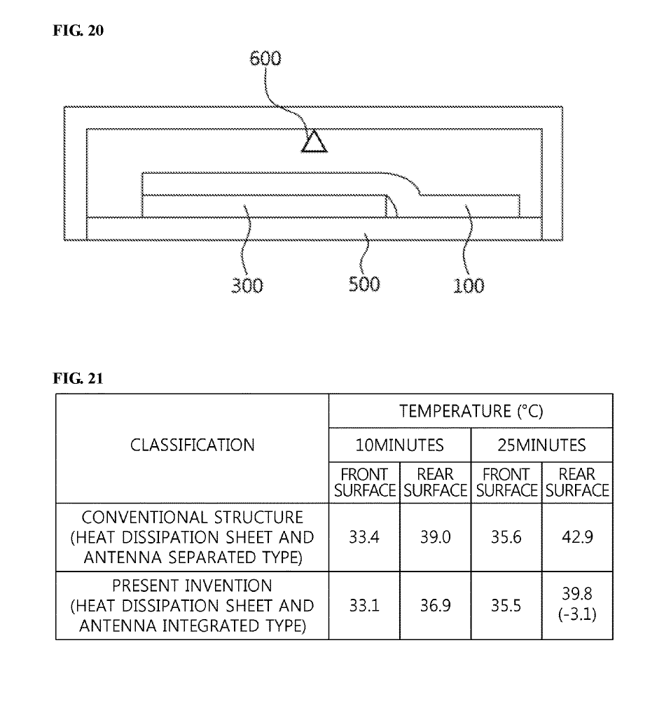

On the other hand, as shown in FIG. 19, the heat dissipation sheet 100 having the slit and the antenna module are provided integrally and mounted on the back cover 500. Here, referring to FIG. 20 showing a cross-section taken along line B-B′ of FIG. 19, since an area reduction of the heat dissipation sheet 100 itself is minimized, and the hot spot 600 is placed in a region where the heat dissipation sheet 100 is mounted, degradation of heat dissipation performance can be prevented.

In addition, a metal material of the antenna module (that is, the antenna pattern 300 and the base sheet 200) serves as the auxiliary heat dissipation member, and thus it is possible to achieve improved heat dissipation performance as compared with a conventional antenna module and a heat dissipation sheet 100 that are manufactured separately.

Referring to FIG. 21, in the case of a separated structure (i.e. conventional structure), a front surface temperature and a rear surface temperature that are measured at 10 minutes and 25 minutes after a start of the test are about 33.4° C. and 35.6° C., and about 39° C. and 42.9° C., respectively.

On the other hand, in the case of an integrated structure (structure according to the embodiment of the present invention), a front surface temperature and a rear surface temperature that are measured at 10 minutes and 25 minutes after a start of the test are about 33.1° C. and 35.5° C., and about 36.9° C. and 39.8° C., respectively.

As a result, it can be seen that when the heat dissipation sheet 100 having the slit is provided integrally with the antenna module, heat dissipation performance is improved by approximately 2.1 to 3.1° C. compared to the separated structure.

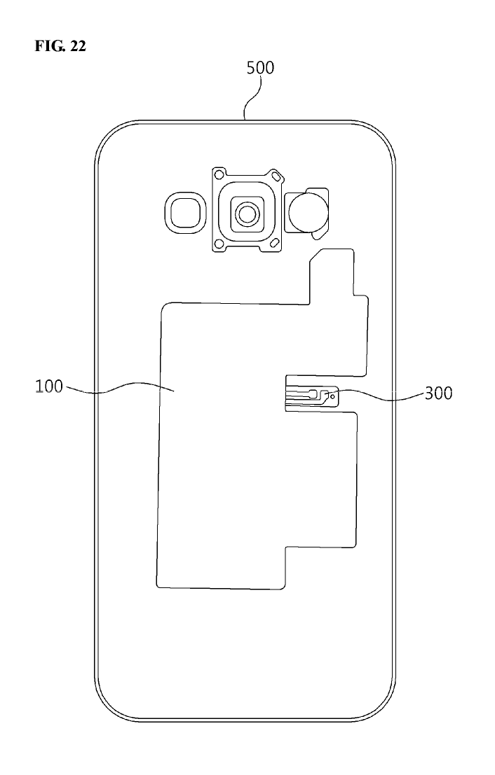

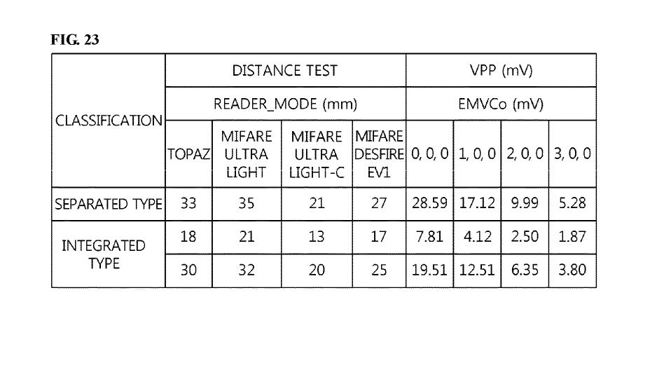

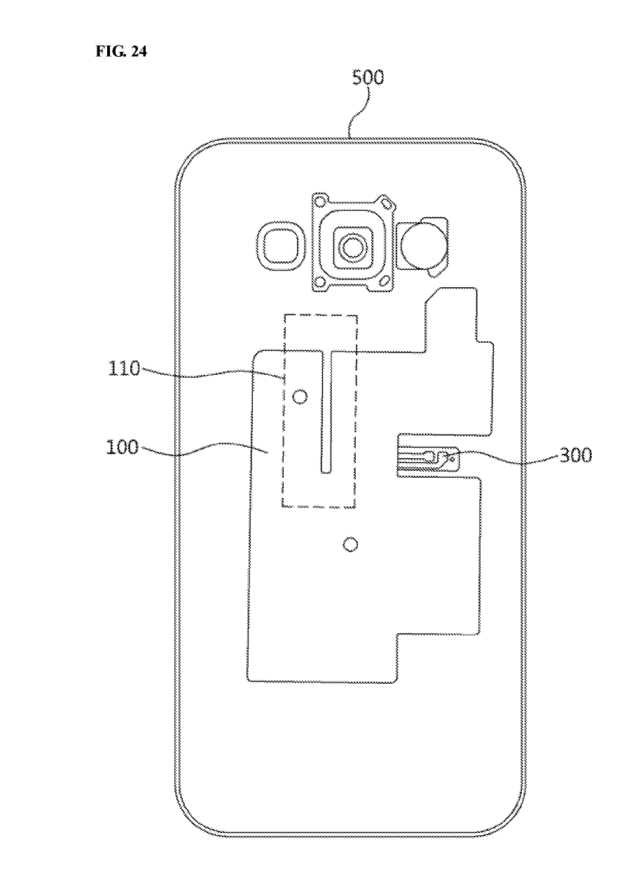

As shown in FIG. 22, when a heat dissipation sheet 100 having no slit is provided integrally with the antenna pattern 300, antenna performance is degraded due to the heat dissipation sheet 100. In other words, the minimum voltage required at the position of PICC of (0, 0, 0) is 8.8 mV, and the minimum voltage required at the position of PICC of (1, 0, 0) is 7.2 mV, the minimum voltage required at the position of PICC of (2, 0, 0) is 5.6 mV, and the minimum voltage required at the position of PICC of (3, 0, 0) is 4 mV. Referring to FIG. 23, it can be seen that when the heat dissipation sheet 100 having no slit and the antenna pattern 300 are provided separately, it is possible to pass evaluation of both recognition distance and minimum voltage. However, when the heat dissipation sheet having no slit and the antenna pattern are provided integrally, the evaluation of both recognition distance and minimum voltage are less than the reference value, and thus antenna performance is degraded.

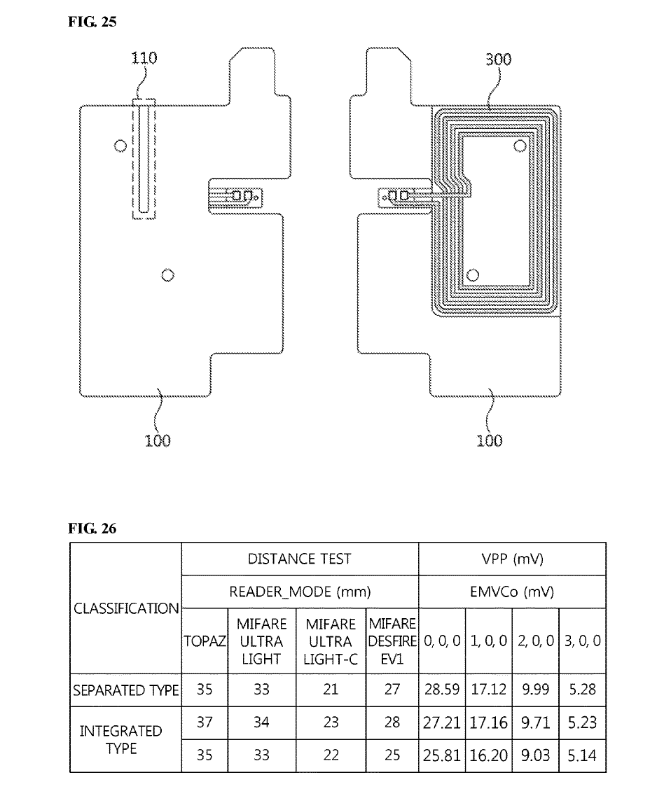

On the other hand, as shown in FIGS. 24 and 25, when a slit is formed in a heat dissipation sheet 100 formed to have the same shape and thickness as the heat dissipation sheet 100 shown in FIG. 22, and the antenna pattern 300 and the heat dissipation sheet 100 are provided integrally, antenna performance can be ensured equally while heat dissipation performance is maintained. Referring to FIG. 26 on the basis of the foregoing, when the heat dissipation sheet 100 having the slit is provided integrally with the antenna pattern 300, the area of the heat dissipation sheet 100 is not reduced, thereby maintaining heat dissipation effect, and it is possible to pass the evaluation of recognition distance and minimum voltage, thereby ensuring antenna performance equal to that of the case where the heat dissipation sheet 100 having no slit and the antenna pattern 300 are provided separately.

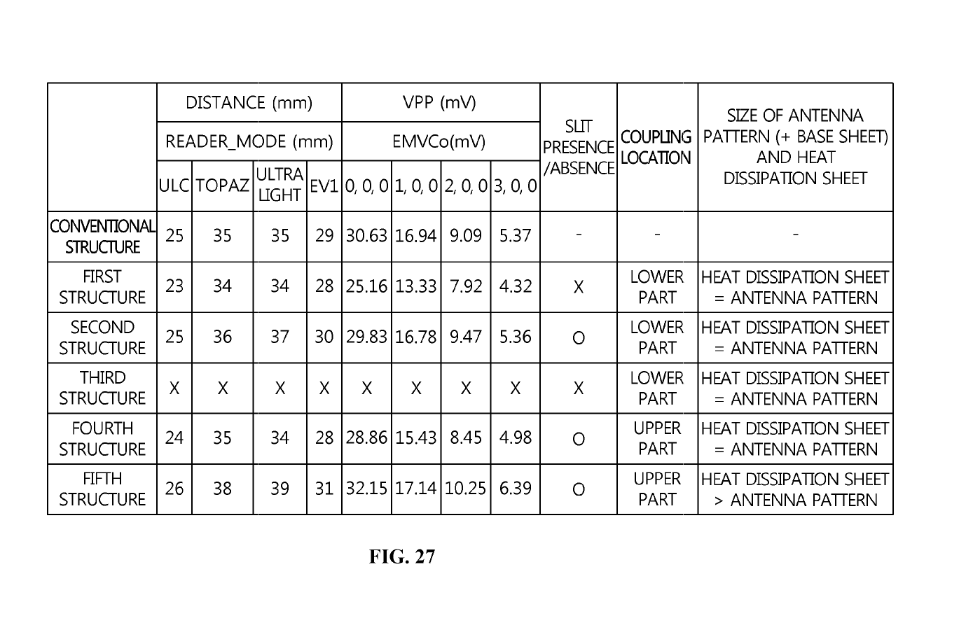

The antenna properties according to the coupling location of the heat dissipation sheet 100, the presence and absence of the slit, and the size of the heat dissipation sheet will be described with reference to FIG. 27. The conventional structure is a structure in which the antenna pattern 300 and the heat dissipation sheet 100 are provided separately. A first structure is a structure in which the heat dissipation sheet 100 having no slit is coupled to the lower surface of the base sheet 200 on which the antenna pattern 300 is formed, and a second structure is a structure in which the heat dissipation sheet 100 having the slit is coupled to the lower surface of the base sheet 200 on which the antenna pattern 300 is formed. The third structure is a structure in which the heat dissipation sheet 100 having no slit is coupled to the upper part of the antenna pattern 300, and a fourth structure is a structure in which the heat dissipation sheet 100 having the slit is coupled to the upper part of the antenna pattern 300. Here, the heat dissipation sheet 100 of the first to fourth structures is formed to have the same size as the base sheet 200 on which the antenna pattern 300 is formed. The fifth structure is the same as the fourth structure except that the size of the heat dissipation sheet 100 is larger than that of the base sheet 200. Here, heat dissipation performance is proportional to the size of the heat dissipation sheet 100. Accordingly, the first to fourth structures have substantially the same heat dissipation performance, and the fifth structure having a relatively large size of the heat dissipation sheet 100 has excellent heat dissipation performance.

Based on the antenna performance of the conventional structure, in the case of the first to second structures, the heat dissipation sheet 100 is coupled to a lower surface of the antenna pattern 300, and thus the antenna properties are maintained to be equal to that of the conventional structure.

However, in the case of the third structure, since the heat dissipation sheet 100 having no slit is coupled to an upper surface of the antenna pattern 300, the antenna properties are not realized. In other words, formation of a radiation field is blocked by the heat dissipation sheet 100, and the antenna pattern 300 cannot transmit or receive a signal.

Meanwhile, in the case of the fourth and fifth structures, since the heat dissipation sheet 100 having the slit is coupled to the upper surface of the antenna pattern 300, the antenna properties are equal to or better than that of the conventional structure. Here, since the heat dissipation sheet 100 serves as the auxiliary radiator of the antenna pattern 300 in the fourth and fifth structures, the fifth structure having a relatively large area has an improved antenna performance as compared with the fourth structure.

As described above, in the heat dissipation sheet-integrated antenna module, the heat dissipation sheet is provided with the slit and is provided integrally with the antenna module, and thus compared with the prior art in which the antenna module and the heat dissipation sheet are provided separately, the area of the heat dissipation sheet is increased, thereby maximizing heat dissipation effect and maintaining antenna performance to be equal to or better than that of the prior art. In particular, even when the heat dissipation sheet is applied to the back cover, the heat dissipation sheet-integrated antenna module has the effect of ensuring the antenna performance equal to that of the case where the heat dissipation sheet is absent, while maintaining heat dissipation performance.

In addition, in the heat dissipation sheet-integrated antenna module, the heat dissipation sheet is provided with the slit and is provided integrally with the antenna module, and thus the antenna pattern and the base sheet that are made of metal serve as the auxiliary heat dissipation member, thereby maximizing heat dissipation effect.

Moreover, in the heat dissipation sheet-integrated antenna module, the heat dissipation sheet is provided with the slit and is provided integrally with the antenna module, and thus the heat dissipation sheet serves as the auxiliary radiator of the antenna pattern by the coupling between the antenna pattern and the heat dissipation sheet in the region where the slit is formed, thereby maximizing antenna performance.

Although the preferred embodiment of the present invention have been disclosed for illustrative purposes, those skilled in the art will appreciate that various modifications, additions and substitutions are possible, without departing from the scope and spirit of the invention as disclosed in the accompanying claims.

1. A heat dissipation sheet-integrated antenna module, the antenna module comprising:
an antenna pattern; and
a heat dissipation sheet having one or more slits and being coupled to the antenna pattern.

2. The antenna module of claim 1, wherein the heat dissipation sheet is coupled to an upper surface of the antenna pattern, such that the antenna pattern is partially exposed through the one or more slits.

3. The antenna module of claim 2, further comprising:
a base sheet attached to the antenna pattern,
wherein the heat dissipation sheet is attached to the base sheet and coupled to the antenna pattern.

4. The antenna module of claim 1, wherein the heat dissipation sheet includes:
a first heat dissipation member having a slit and being coupled to the antenna pattern; and
a second heat dissipation member having a slit and coupled to the antenna pattern at a location spaced apart from the first heat dissipation member,
wherein the antenna pattern is partially exposed through a slit formed at a region where the first and second heat dissipation members are spaced apart from each other, and through the slits formed at the first and second heat dissipation members.

5. The antenna module of claim 4, wherein the heat dissipation sheet further includes:
a third heat dissipation member spaced apart from the first and second heat dissipation members at the region where the first and second heat dissipation members are spaced apart from each other, the third heat dissipation member being coupled to the antenna pattern,
wherein the antenna pattern is partially exposed through slits formed at regions where the first and second heat dissipation members are spaced apart from the third heat dissipation member.

6. The antenna module of claim 1, wherein the heat dissipation sheet includes:
a first heat dissipation member provided at a side thereof with a slit and coupled to the antenna pattern; and
a second heat dissipation member provided at a side thereof with a slit and coupled to the antenna pattern at a location spaced apart from the first heat dissipation member,
wherein the antenna pattern is partially exposed through a slit formed at a region where the first and second heat dissipation members are spaced apart from each other, and through the slits provided at the first and second heat dissipation members.

7. The antenna module of claim 6, wherein the first and second heat dissipation members are placed such that the sides thereof at which the slits are provided face each other.

8. The antenna module of claim 1, wherein the heat dissipation sheet includes:
an insulation layer composed of a porous substrate having a plurality of fine pores that form air pockets capable of trapping air, or of a graphite layer.

9. The antenna module of claim 8, wherein the porous substrate includes:
one of a nano-fiber web, a non-woven fabric, and a laminated structure of the nano-fiber web and the non-woven fabric, each of the nano-fiber web, the non-woven fabric, and the laminated structure having a plurality of pores formed by accumulating nano-fibers.
